(19) United States
(12) Patent Application Publication
(10) Pub. No.: US 2014/0008722 A1
(43) Pub. Date: Jan. 9, 2014

(54) VERTICAL-GATE MOS TRANSISTOR WITH FIELD-PLATE ACCESS

(71) Applicant: STMicroelectronics S.r.l., Agrate Brianza (IT)

(72) Inventors: Simone Dario MARIANI, Vedano al Lambro (IT); Daniele MERLINI, Milan (IT); Fabrizio Fausto Renzo TOIA, Busto Arsizio (IT)

(21) Appl. No.: 13/927,600

(22) Filed: Jun. 26, 2013

(30) Foreign Application Priority Data
Jun. 26, 2012 (IT) MI2012A001123

(51) Int. Cl. H01L 29/78; H01L 29/66

(52) U.S. Cl. CPC H01L 29/7827; H01L 29/66666
USPC 257/334; 438/589

(57) ABSTRACT

An embodiment of a vertical-gate transistor disposed on a die includes a first substrate portion of a first conductivity and a second substrate portion of a second conductivity. The die includes front and rear surfaces, the first portion extending from the front surface and the second portion extending from the rear surface to the first portion, at least one drain region of the second conductivity extending from the rear surface, and at least one cell. Each cell includes a source region of the second conductivity extending from the front surface, a conductive gate region extending from the front surface to a gate depth, a conductive field-plate region extending from the front surface to a field depth, a gate-insulating layer that insulates the gate region, and a plate-insulating layer that insulates the field-plate region. An intermediate insulating layer insulates the gate region from the field-plate region.

### PRIORITY CLAIM

The instant application claims priority to Italian Patent Application No. MI2012A001123, filed Jun. 26, 2012, which application is incorporated herein by reference in its entirety.

### SUMMARY

An embodiment generally relates to semiconductor devices. In more detail, an embodiment refers to field-effect transistors.

Recently, the growing trend of increasing the integration density of semiconductor devices has led to the reduction of the size of the elements used in integrated circuits (a process called “scaling”), to allow the manufacturing of complete integrated electronic systems—in particular, including one or more circuits for management and distribution of electrical energy (often called “power circuits”) next to signal-processing circuits.

A basic integrated-circuit element is the transistor; particularly, in circuits having high integration density, the use of field-effect transistors, and in particular of the MOS type, is predominant. The integrated MOS transistors for power applications (such as in driving circuits for liquid-crystal displays and the like), in addition to being formed with small dimensions, are also often able to withstand relatively high voltages (e.g., 10 Volts (V)-70V).

The limitations in the manufacturing of MOS transistors of small dimensions often arise from the length of a channel region of the transistor (between a source region and a drain region). A well-defined channel length is important for the correct operation of the MOS transistor; indeed, many electric-characteristic parameters, such as the transconductance, depend on the channel length. Moreover, as soon as the channel length is reduced from its minimum well-defined value, the correct operation of the MOS transistor as a whole may be penalized due to short-channel effects, for example, punch-through or permanently short-circuited channel phenomena (which phenomena are accentuated by the high voltages in the power transistors).

To solve the problems related to the phenomena just mentioned, vertical-gate MOS transistors (also known as Vertical-Trench MOS (VTMOS) transistors) have been developed. In a MOS transistor of this type, a trench is formed in a front surface of a chip of semiconductor material on which the MOS transistor is to be integrated. The walls of the trench are covered with a layer of gate oxide; the trench is then filled with a conductive material (typically a layer of polycrystalline silicon or polysilicon) suitable to form a gate region in its outer part and a field-plate region in its inner part (having the purpose of controlling the intensity of the electric field in the channel region). The source and drain regions of the MOS transistor are formed at the front surface and at a rear surface of the chip, respectively.

During operation, the channel region extends along the vertical and bottom walls of the trench, between the source and drain regions. In this way, even if the total size (e.g., the total area) of the MOS transistor is reduced, the channel region may be maintained sufficiently long so as to prevent the short-channel effects. Furthermore, the field-plate region allows controlling the concentration of carriers in the channel region and reducing or controlling a corresponding operating resistance (on-resistance) of the MOS transistor.

However, in conventional VTMOS transistors, the field-plate region may be intercoupled to the gate region; consequently, in such transistors, the field-plate region is always biased as the gate region. This constrains the adjustment of the electric field generated in the channel region to the biasing of the gate region

In general terms, an embodiment is based on the idea of separating the gate region and the field-plate region.

More specifically, an embodiment is a vertical-gate MOS transistor integrated on a chip of semiconductor material, wherein a field-plate region extends from a front surface of the chip and is insulated from a gate region.

A further embodiment is a system including one or more of such vertical-gate MOS transistors.

A further embodiment is a corresponding method for forming a vertical-gate MOS transistor.

### BRIEF DESCRIPTION OF THE DRAWINGS

One or more embodiments, as well as features and advantages thereof, will be better understood with reference to the following detailed description, given purely by way of a non-restrictive indication and without limitation, to be read in conjunction with the attached figures (wherein corresponding elements are denoted with equal or similar references and their explanation is not repeated for the sake of brevity). In this respect, it is expressly understood that the figures are not necessarily drawn to scale (with some details that may be exaggerated or simplified) and that, unless otherwise specified, the figures are intended to conceptually illustrate one or more embodiments of the structures and procedures described herein. In particular:

FIG. 1 is a schematic cross-sectional view of a portion of a vertical-gate MOS transistor, according to an embodiment.

FIG. 2 is a schematic plan view of a vertical-gate MOS transistor, according to an embodiment.

FIGS. 3A-3J illustrate some steps of a process for forming a gate region and a field-plate region of a vertical-gate MOS transistor, according to an embodiment.

### DETAILED DESCRIPTION

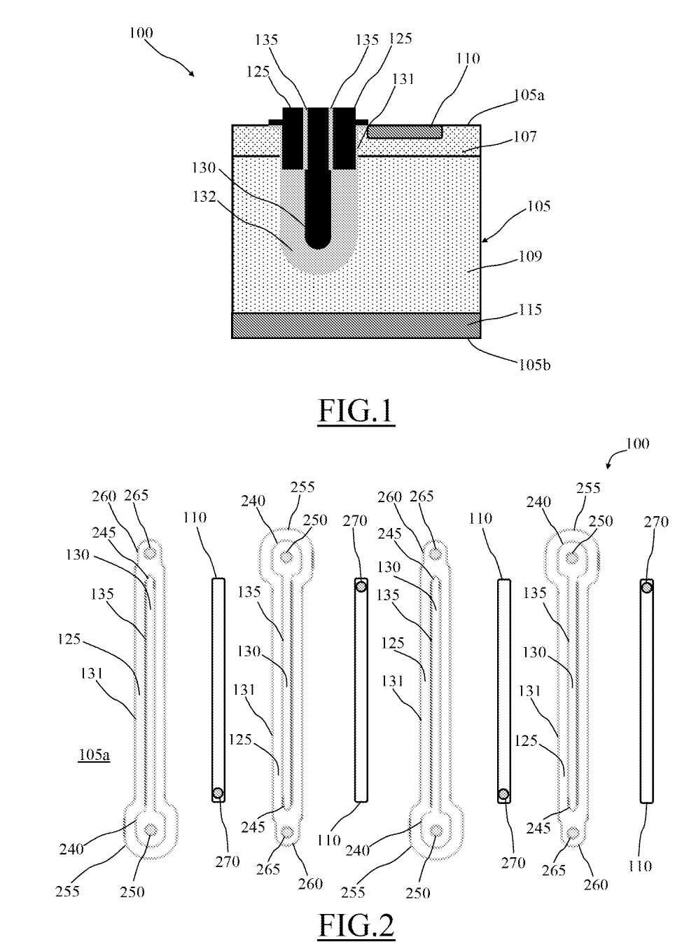

With reference to FIG. 1, there is shown a schematic cross-sectional view of a portion of a vertical-gate MOS transistor 100, according to an embodiment.

The transistor 100 is integrated on a chip that includes a substrate 105 of semiconductor material (e.g., Silicon), which has a front surface 105a and a rear surface 105b opposite to the front surface 105a. The substrate 105 includes a first substrate portion 107 having a first doping, for example P-type (as in the case of Silicon doped with Boron), that extends from the front surface 105a towards the inside of the substrate 105 (down to a first depth). Moreover, the substrate 105 includes a second substrate portion 109 having a second doping (opposite the first doping), for example N-type (as in the case of Silicon doped with Phosphor), that extends from the first portion 107 (i.e., from the first depth) down to the rear surface 105b. For example, the second substrate portion 109 has a greater extent than the first substrate portion 107. A source region 110, for example of the N-type, extends from the front surface 105a towards the inside of the substrate 105 (within the first portion 107). A layer that defines a drain region 115, for example of the N-type, (for example, with a higher dopant concentration than the second substrate portion 109 of the substrate 105) extends from the rear surface 105b towards the inside of the substrate 105 (within the second substrate portion 109 up to a drain distance Dd from the rear surface 105b). Alternatively, the drain region may be defined in a different way, such as for example by a layer grown on the rear surface 105b of the substrate 105.

Moreover, a gate region 125 of conductive material (e.g., polysilicon) extends into the substrate 105 from the front surface 105a to a depth Dg (with the depth Dg, for example, being greater than the first depth); a corresponding field-plate region 130 of conductive material (for example, again polysilicon) extends into the substrate 105 to a depth Dp>Dg (e.g., Dp≈2-4·Dg). A gate-insulating layer 131 with a thickness Tg (for example, silicon oxide) insulates the gate region 125 from the substrate 105; a plate-insulating layer 132 with a thickness Tp>Tg, for example, Tp≈2-4˜Tg (e.g., again of silicon oxide) insulates the field-plate region 130 from the substrate 105. Although not shown, the source region 110, gate region 125, field-plate region 130, and insulating regions 131, 132, and 135 (described below) may each have more than the one portion shown in FIG. 1 as, for example, described below in conjunction with FIG. 2.

According to an embodiment, also the field-plate region 130 extends from the front surface 105a (e.g., inside the gate region 125). In addition, the gate region 125 and the field-plate region 130 are electrically insulated from each other through an intermediate insulating layer 135 arranged between them (e.g., again of silicon oxide).

The structure according to an embodiment described above, allows electrically contacting the gate region 125 and the field-plate region 130 individually. Accordingly, it is possible to independently control both an intensity of the drain-source current generated in the structure—by controlling a biasing of the gate region 125—and a trend of the electric field in the channel region of the substrate 105, between the source region 110 and the drain region 115—by controlling a biasing of the field-plate region 130.

Turning now to FIG. 2, it is a schematic plan view of the vertical-gate MOS transistor 100 of FIG. 1, according to an embodiment.

The vertical-gate MOS transistor 100 has a cellular structure, with a plurality of cells each one including a source region 110, a gate region 125 and a field-plate region 130, with the corresponding insulating layers (of which only the insulating layers 131 and 135 are visible in the figure).

Each field-plate region 130 has (on the front surface 105a) an elongated shape with an enlarged end 240 substantially circular and an opposite narrow end 245; an electrical plate contact 250 (e.g., of metal) is formed on the enlarged end 240 for electrically contacting the field-plate region 130. The gate region 125 surrounds the field-plate region 130 on the front surface 105a, thus it is shaped in a manner similar to the latter with an elongated shape having an enlarged end 255 substantially circular and an opposite narrow end 260; a gate contact 265 is formed on the narrow end 260 for electrically contacting the gate region 125.

Each gate region 125 (with the corresponding inner field-plate region 130) forms a finger of an interdigitated structure. In detail, the gate regions 125 are arranged side by side in parallel, one reversed with respect to the other, so that the narrow end 260 of each gate region 125 (with the exception of the first one and the last one) is arranged between the enlarged ends 250 of two adjacent gate regions 125. In addition, each source region 110 is arranged next to a respective gate region 125, between the latter and a subsequent gate region 125 included in the cellular structure. In particular, each source region 110 has an elongated shape, and extends at the side of an approximately constant-width portion of the gate region 125. A source contact 270 is formed along the source region 110 for electrically contacting it.

All the gate contacts 265, all the field-plate contacts 250 and all the source contacts 270 are electrically coupled together (for example, through corresponding metal tracks) so as to define a gate terminal, a field-plate terminal, and a source terminal, respectively (not shown in the figure for the sake of simplicity). In addition, a drain contact is formed on the rear surface of the substrate 105 (not visible in FIG. 2) for contacting the (single) drain region, so as to define a drain terminal.

The interdigitated structure allows obtaining an electric current flow of high intensity without an excessive overheating of the MOS transistor 100 (since the electric current flow is divided among the fingers of the interdigitated structure, and it is distributed along their large perimeter).

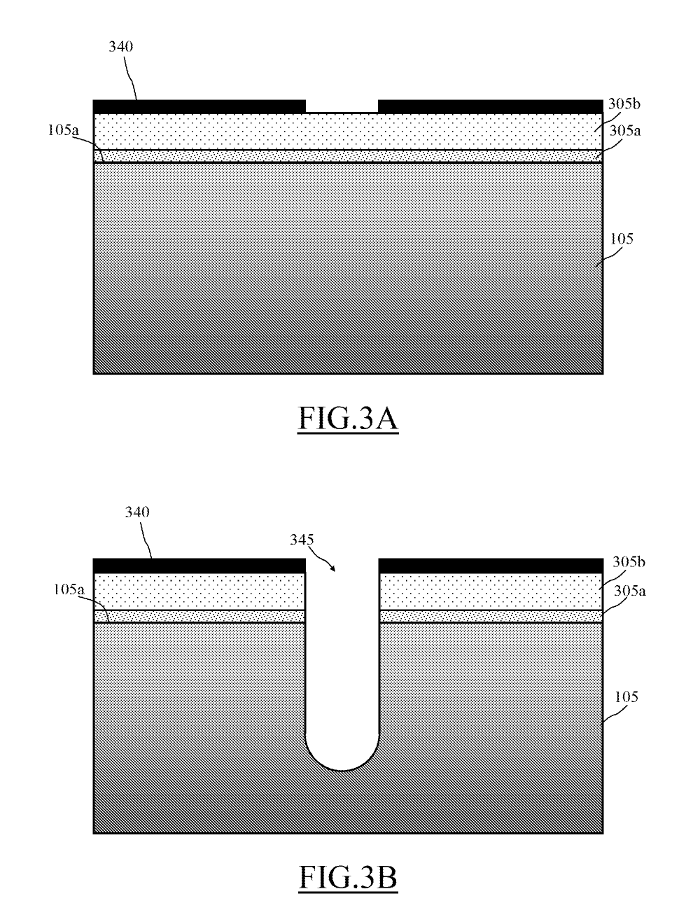

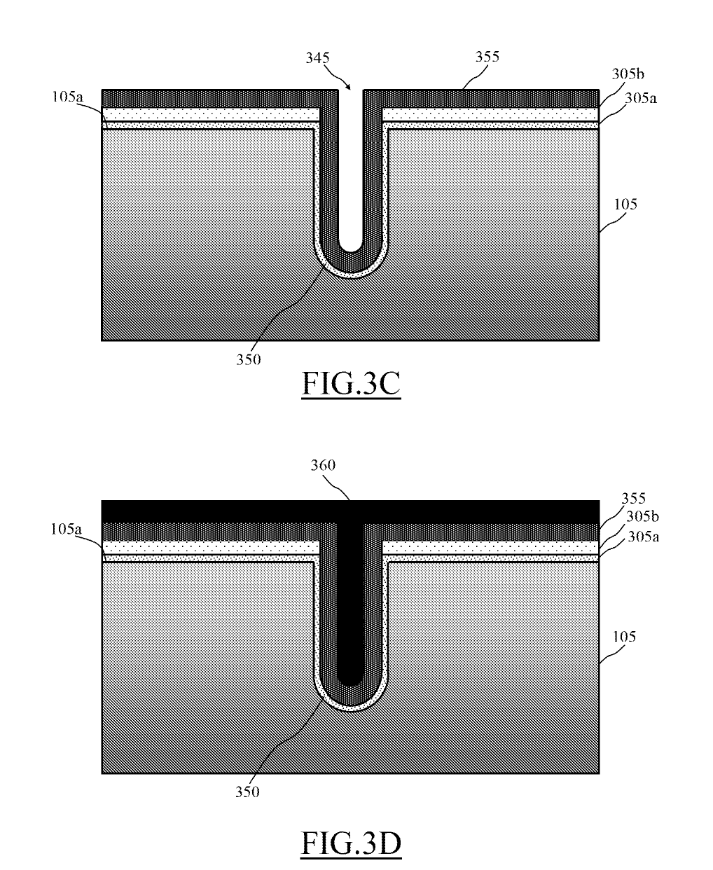

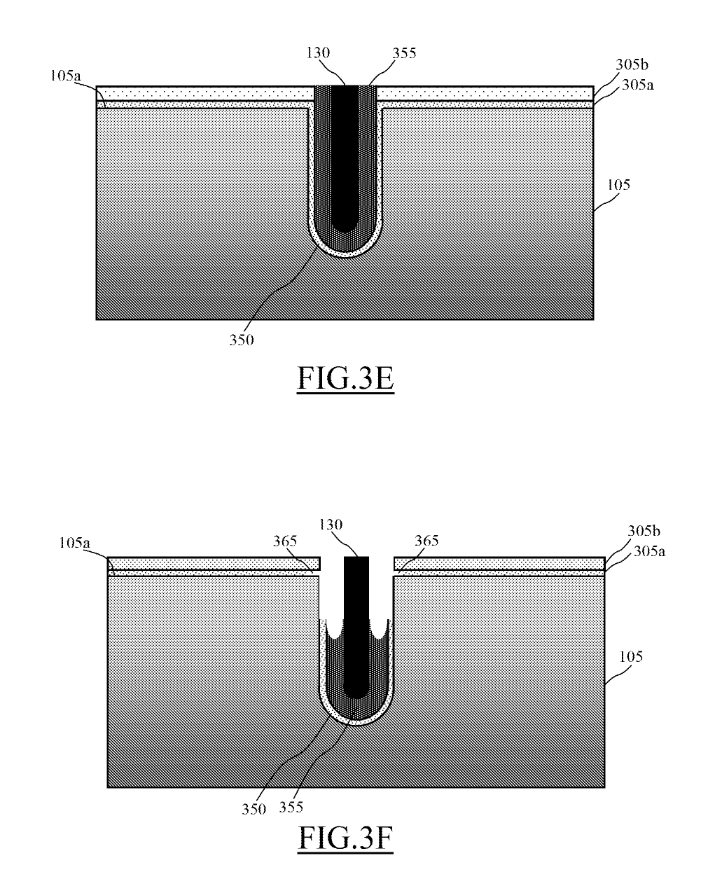

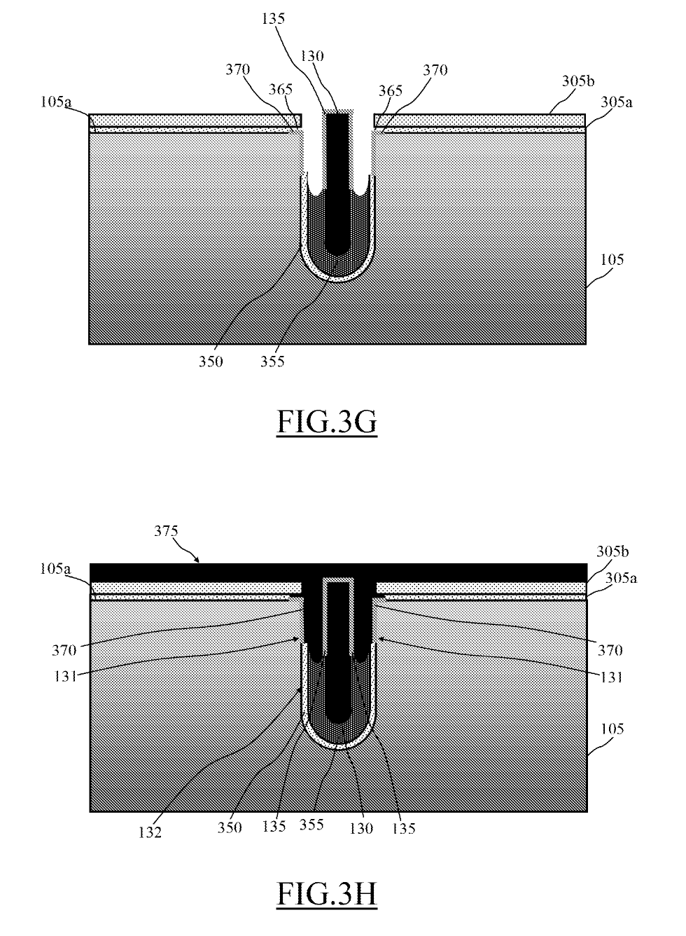

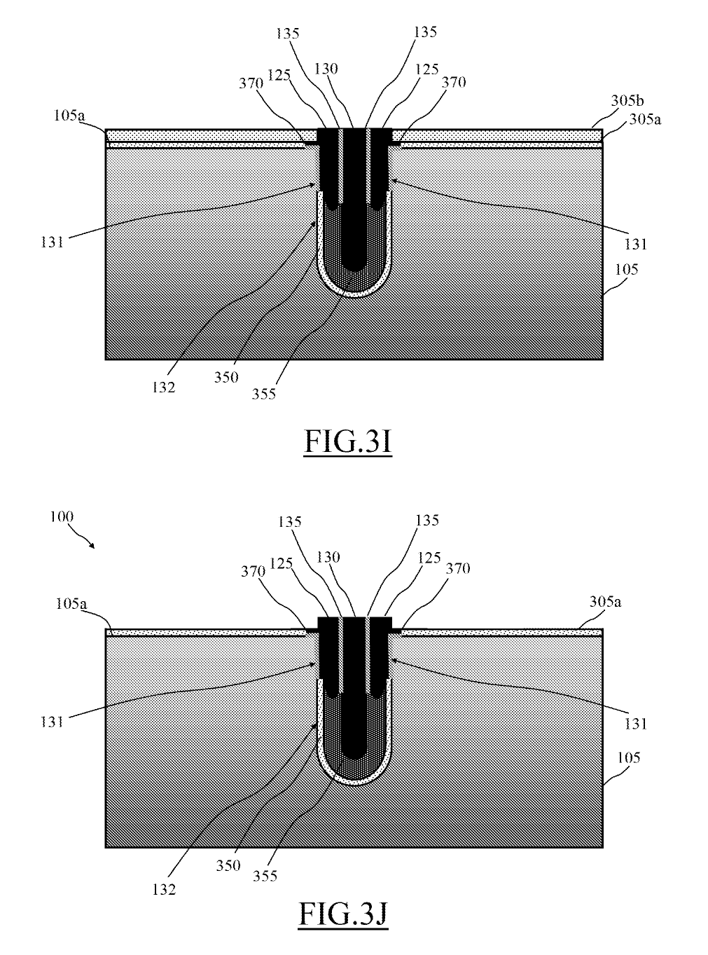

Considering now FIGS. 3A-3J together, some steps of a process of forming a vertical-gate region and a field-plate region of a vertical-gate MOS transistor are illustrated, according to an embodiment.

Considering in particular FIG. 3A, the process is described starting from a structure including the substrate 105, a (surface) insulating layer 305a (for example, silicon oxide SiO₂) arranged on its front surface 105a, and a (sacrificial) insulating layer 305b (including one or more stacked insulating sub-layers—for example, a tetraethyl orthosilicate (TEOS) sub-layer and a silicon nitride (SiN) sub-layer, not detailed in FIGS. 3A-3J for the sake of simplicity) arranged on the insulating layer 305a. A photolithographic mask 340 is arranged on the insulating layer 305b, with a window that exposes a portion thereof wherein the gate region and the field-plate region will be formed.

Turning to FIG. 3B, the entire structure is subject to an anisotropic etching (e.g., by means of a plasma such as in the Reactive Ion Etching (RIE) technique). Therefore, a trench 345 extending into the substrate 105 from the front surface 105a is formed through the window of the photolithographic mask 340. Thus, the photolithographic mask 340 is removed together with a part of the insulating layer 305b.

With reference now to FIG. 3C, the entire structure is subject to thermal oxidation (for example, a dry thermal oxidation at temperatures between approximately 800° C. and 1100° C.), during which a wall of the substrate 105 that delimits the trench 345 reacts with molecular oxygen forming an (outer) insulating layer 350 of silicon oxide having a thickness Te, which connects to the insulating layer 305a.

Subsequently, the entire structure is subject to a step of Chemical Vapour Deposition (CVD) through which an (inner) insulating sub-layer 355 (e.g., silicon oxide) is deposited on the insulating layer 305b and on the insulating sub-layer 350 (inside the trench 345). In particular, the insulating sub-layer 355 is formed with a thickness Ti greater than the thickness Te of the insulating sub-layer 350 (e.g., Ti≈2-50·Te, for example Ti≈5-30·Te, or even Ti≈10-20·Te, such as Te≈15·Ti). Furthermore, the thickness Ti is such that the insulating sub-layer 355 takes a substantial portion of the trench 345. For example, the step of CVD deposition may have a duration such as to obtain the insulating sub-layer 355 with the thickness Ti equal to approximately 0.1 to 0.7, for example approximately 0.2 to 0.5, or even approximately 0.25 to 0.4, such as approximately equal to 0.3 times a width of the cross section of the trench 345.

Turning to FIG. 3D, a layer of conductive material 360 (e.g., polysilicon) is deposited on the insulating sub-layer 355, in such a way to fill a free space remaining in the trench.

Subsequently, as shown in FIG. 3E, an excess of conductive material and insulating material that covers the insulating layer 305b is removed by a step of Chemical Mechanical Planarization (CMP) down to expose the insulating layer 305b again; in this way, the remaining portion of the layer of conductive material deposited inside the trench defines the field-plate region 130.

Turning now to FIG. 3F, the insulating sub-layer 350 and the insulating sub-layer 355 are chemically etched (e.g., by means of hydrogen fluoride). In detail, the etching is configured so as to have an etch rate on the insulating sub-layer 355 greater than an etch rate on the insulating sub-layer 350 (e.g., with a ratio equal to approximately 10-100, for example, equal to approximately 20-70, and even equal to approximately 30-60, such as equal to approximately 50). Therefore, the insulating sub-layer 355 is removed from the front surface 105a down to the gate depth Dg whereas the insulating sub-layer 350 is removed down to a depth De lower than the gate depth Dg (with the simultaneous formation of a hollow in the insulating sub-layer 355) for example, De=approximately 0.8 to 0.95·Dg. In this way, a portion of the field-plate region 130 and a portion of the wall of the substrate 105 that delimits the trench, proximal to the front surface 105a of the substrate 105, remain exposed. In addition, also a portion of the insulating layer 305a is removed around the trench on the front surface 105a, thereby forming corresponding recesses 365 under the insulating layer 305b.

Subsequently, as shown in FIG. 3G, the entire structure is subject to another thermal oxidation, in order to form the (intermediate) insulating layer 135 around the portion of the exposed plate region 130 and, at the same time, an insulating layer 370 on the portion of the wall of the substrate 105 exposed after the chemical etching. In particular, the insulating layer 135 and the insulating layer 370 are formed with a thickness Ts lower than the thickness Te of the insulating sub-layer 350 (e.g., Te≈2-10·Ts, for example Te≈3-6·Ts, such as Te≈5·Ts).

In a next step, shown in FIG. 3H, a layer of conductive material 375 (e.g., polysilicon) is deposited again on the whole structure. In particular, the conductive material 375 fills the portion of the trench freed by the previous chemical etching and the recesses on the front surface 105a of the substrate 105, and then covers the insulating layer 305b.

Turning now to FIG. 31, an excess of conductive material 375 and the portion of the insulating layer 135 formed on an upper portion of the field-plate region 130 are removed through another chemical-mechanical planarization, which again exposes the insulating layer 305b and the upper portion of the field-plate region 130. In this way, the gate region 125 is fully formed and is electrically insulated from the field-plate region 130 thanks to the insulating layer 135 interposed between them. In particular, the gate region 125 surrounds the field-plate region 130 on the front surface 105a, so that the desired result is achieved by maintaining the layout of the MOS transistor (and, therefore, at least some aspects of its operation) substantially unchanged. Finally, another chemical etching (e.g., with Phosphoric acid H₃PO₄) completely removes the insulating layer 305b.

Therefore, as shown in FIG. 3J, the front surface 105a of the substrate 105 remains covered only by the insulating layer 305a, which has the purpose of electrically insulating and protecting it, with the gate region 125 and the plate region 130 that protrude above it.

The recesses previously filled with conductive material form an additional surface portion of the gate region 125, which is exposed on the substrate surface 105a flush with the insulating layer 105b; this may facilitate the subsequent formation of the gate contact.

Furthermore, the gate-insulating layer 131 that insulates the gate region 125 from the substrate 105 includes the insulating layer 370, a portion of the insulating sub-layer 350 (adjacent to an end of the insulating layer 370 distal from the front surface 105a) and a portion of the sub-layer 355 that surrounds a portion of the gate region 125 formed in the hollow of the inner insulating sub-layer 355 (distal from the front surface 105a). Consequently, the gate-insulating layer 131 has a thin operating insulating portion (with a thickness equal to that of the insulating layer 370) and a thicker transition insulating portion (with a thickness that increases to that of the insulating sub-layer 350 with the subsequent addition of part of the insulating sub-layer 355). Therefore, during operation of the MOS transistor, the gate electric field generated—through a predetermined biasing of the gate region 125—in the substrate 105 adjacent to the gate-insulating layer 131 is characterized by an intensity approximately constant in portions of the substrate 105 adjacent to the insulating layer 370 that decreases (away from the front surface 105a) in portions of the substrate adjacent to the insulating sub-layer 350. This allows obtaining a modulation of the electric field generated by the gate region 125.

In the particular embodiment described above, this result is achieved by varying the thickness of the gate region 125 around the field-plate region 130 correspondingly. In this way, it may be possible to maintain an outer surface of the gate-insulating layer 131 planar (although with variable thickness).

The (plate) insulating layer 132 instead includes the insulating sub-layer 355 and the insulating sub-layer 350. In detail, the insulating sub-layer 350, formed by thermal oxidation, is formed by an oxide with high density and thus able to withstand high voltages that may arise at the ends thereof (ensuring high strength and reliability of the MOS transistor). Otherwise, the insulating sub-layer 355, formed through a vapor-phase deposition, has a lower density and thus less resistance to these voltages. However, the deposition of the insulating sub-layer 355 is much faster than the thermal oxidation and, unlike the latter, does not affect the substrate 105. Therefore, the insulating layer 132 is resistant to high voltages thanks to the insulating sub-layer 350 and, at the same time, is obtainable in a fast and economical way thanks to the insulating sub-layer 355.

It is noted that an embodiment of the process described above allows obtaining the gate region 125 and the field-plate region 130 electrically insulated and physically separated from each other through the use of a single lithographic mask and with a limited number of simple process steps. Therefore, an embodiment of this process is simple and economical.

Naturally, in order to satisfy local and specific requirements, one may apply to the one or more embodiments described above many logical or physical modifications and alterations. More specifically, although one or more embodiments have been described with a certain degree of particularity, it is understood that various omissions, substitutions, and changes in the form and details as well as other embodiments are possible. Particularly, different embodiments may even be practiced without the specific details (such as the numerical examples) set forth in the preceding description to provide a more thorough understanding thereof; conversely, well-known features may have been omitted or simplified in order not to obscure the description with unnecessary particulars. Moreover, it is expressly intended that specific elements or method steps described in connection with any embodiment may be incorporated in any other embodiment as a matter of general design choice. In any case, the terms “comprising,” “including,” “having,” and “containing” (and any of their forms) are to be understood with an open and non-exhaustive meaning (i.e., not limited to the recited elements), the terms “based on,” “dependent on,” “according to,” “function of” (and any of their forms), are to be understood as a non-exclusive relationship (i.e., with possible further variables involved), and the term “a” is to be understood as one or more elements (unless expressly stated otherwise).

For example, an embodiment is a vertical-gate MOS transistor integrated on a chip of semiconductor material of a first conductivity type. The chip has a front surface and a rear surface opposite the front surface. The transistor includes at least one drain region of a second conductivity type extending in the chip from the rear surface, and at least one cell. Each cell includes a source region of the second conductivity type extending into the chip from the front surface, a gate region of conductive material extending into the chip from the front surface to a gate depth, a field-plate region of conductive material extending into the chip to a field depth greater than the gate depth, a gate-insulating layer with a gate thickness that insulates the gate region from the chip, and a plate-insulating layer with a plate thickness greater than the gate thickness that insulates the field-plate region from the chip. In an embodiment, the field-plate region extends from the front surface; the transistor further including an intermediate insulating layer that insulates the gate region from the field-plate region.

However, similar considerations apply if the N-type regions are replaced with P-type regions, and vice versa, or if the different regions have different concentrations of impurities; in addition, the transistor may have a different layout (even non-interdigitated), and its regions may be of any shape, size, and in any position and number (at the limit single ones in a non-cellular structure).

In an embodiment of the MOS transistor, the gate region surrounds the field-plate region on the front surface.

However, nothing prevents a different mutual arrangement between the gate region and the field-plate region. For example, the gate region may simply be arranged at a side of the field-plate region.

In an embodiment of the MOS transistor, the gate-insulating layer includes an operating insulating portion proximal to the front surface with an operating thickness and a transition insulating portion distal from the front surface with a transition thickness greater than the operating thickness.

However, the transition thickness and the operating thickness may have a different relationship between them. Furthermore, the gate-insulating layer may also be with uniform thickness.

In an embodiment of the MOS transistor, the gate region includes an operating gate portion proximal to the front surface with an operating width around the field-plate region and a transition gate portion distal from the front surface with a transition width around the field plate smaller than the operating width. The operating gate portion is surrounded by the operating insulating portion and the transition gate portion is surrounded by the transition insulating portion.

However, the operating gate portion and the transition gate portion may have a different relationship between them. For example, the operating gate portion and the transition gate portion may have a same width (with the corresponding insulating layers protruding according to their thickness).

In an embodiment of the MOS transistor, said at least one plate-insulating layer includes an outer insulating sub-layer with an outer thickness and an inner insulating sub-layer with an inner thickness greater than the outer thickness. The inner insulating sub-layer is interposed between the field-plate region and the outer insulating sub-layer.

However, the outer thickness and the inner thickness may have a different relationship between them. Furthermore, the field-insulating layer may also be a monolayer with uniform thickness.

Another embodiment is a system including one or more of the MOS transistors according to an embodiment.

For example, an embodiment of a VTMOS transistor with a gate region insulated from a field-plate region (or an integrated circuit including such a VTMOS transistor) may be used in a power application within a system, such as an automobile or motor driver, in which a computing apparatus such as a microprocessor or microcontroller controls the operation of the transistor via the transistor's control node (e.g., gate). The computing apparatus may be disposed on an integrated circuit that is on a same die as, or on a different die than, the transistor (or an integrated circuit including the transistor); or the computing apparatus may be part of the same integrated circuit on which the transistor is disposed. Furthermore, where the transistor is disposed on an integrated circuit, it may be the only component, or one of multiple components, on the integrated circuit.

However, such system may be of any type, even of non-power type (e.g., a mobile phone).

In general, similar considerations apply if the vertical-gate MOS transistor, or the system that includes it, each have a different structure or includes equivalent components (e.g., in different materials), or the transistor has other operating characteristics. In any case, any of the transistor's or system's components may be separated into several elements, or two or more components may be combined into a single element; moreover, each component may be replicated for supporting the execution of the corresponding operations in parallel. It is also noted that (unless stated otherwise) any interaction between different components generally need not to be continuous, and may be direct or indirect via one or more intermediaries.

Moreover, an embodiment might be part of the design of an integrated circuit. The design may also be created in a programming language; in addition, if the designer does not manufacture the integrated circuit or its masks, the design may be transmitted through physical means to others. Anyway, the resulting integrated circuit may be distributed by its manufacturer in the form of a raw wafer, as a naked chip, or in a package.

Another embodiment is a method for integrating a vertical-gate MOS transistor on a chip in the semiconductor material of a first conductivity type. The chip has a front surface and a rear surface opposite the front surface. The embodiment includes the following steps. At least one drain region of a second conductivity type extending into the chip from the rear surface is formed. At least one cell is formed; for each cell the embodiment includes the following steps. A source region of the second conductivity type extending into the chip from the front surface is formed. A gate region of conductive material extending into the chip from the front surface to a gate depth is formed. A field-plate region of conductive material extending into the chip to a plate depth greater than the gate depth is formed. A gate-insulating layer with a gate thickness that insulates the gate region from the chip is formed. A plate-insulating layer with a plate thickness greater than the gate thickness that insulates the field-plate region from the chip is formed. In an embodiment, the field-plate region is formed extending from the front surface, and an intermediate insulating layer that insulates the gate region from the field-plate region is formed.

However, similar considerations apply if the MOS transistor is produced with different technologies, with masks different in number and type, or with other process parameters. In an embodiment of a method for integrating a MOS transistor, a step of forming at least one cell includes, for each cell, forming a trench in the chip extending from the front surface, forming an insulating layer in correspondence to a surface of the trench, filling the trench with the conductive material of the field-plate region, removing a portion of the insulating layer down to the gate depth, forming a further insulating layer in correspondence to the surface of the trench exposed by the removal of the portion of the insulating layer and forming the intermediate insulating layer around a portion of the plate region exposed by the removal of the portion of the insulating layer, and replacing the removed portion of the insulating layer with the conductive material of the gate region.

However, nothing prevents one from forming the further insulating layer and the intermediate insulating layer through distinct steps.

In an embodiment of a method for integrating a MOS transistor, a step of forming the insulating layer in correspondence to a surface of the trench includes forming an outer insulating sub-layer with an outer thickness by thermal oxidation, and forming an inner insulating sub-layer with an inner thickness greater than the outer thickness by chemical deposition on the outer sub-layer.

However, nothing prevents one from forming the insulating sub-layers through different techniques or with a different ratio between their thicknesses.

In an embodiment of a method for integrating a MOS transistor, a step of removing a portion of the insulating layer includes removing the inner insulating sub-layer down to the gate depth and the outer insulating sub-layer down to a depth lower than the gate depth.

However, nothing prevents removing the insulating sub-layers at different depths; for example, both insulating sub-layers may be removed down to the same depth.

In an embodiment of a method for integrating a MOS transistor, a step of removing a portion of the insulating layer includes removing the portion of the insulating layer by chemical etching, the chemical etching having an inner etch rate on the inner insulating sub-layer and an outer etch rate on the outer insulating sub-layer lower than the inner etch rate.

However, nothing prevents one from removing the portion of the insulating layer through different techniques, for example, via a plasma etching.

In general, similar considerations may apply if an embodiment is implemented by an equivalent method (using similar steps, removing some steps that are not essential, or adding further optional steps); moreover, the steps may be performed in a different order, in parallel, or overlapped (at least in part).

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1-10. (canceled)

11. A transistor, comprising:
a substrate;
a first field plate disposed in the substrate;
a first gate disposed in the substrate adjacent to the field plate; and
a first insulator disposed between the field plate and the substrate, between the gate and the substrate, and between the gate and the field plate.

12. The transistor of claim 11 wherein the field plate includes a portion that extends beyond the substrate.

13. The transistor of claim 11 wherein the gate includes a portion that extends beyond the substrate.

14. The transistor of claim 11 wherein the gate is adjacent to multiple sides of the field plate.

15. The transistor of claim 11 wherein the insulator includes:
a first portion disposed between the field plate and the substrate;
a second portion disposed between the gate and the substrate; and
a third portion disposed between the gate and the field plate.

16. The transistor of claim 11 wherein the insulator includes:
a first portion disposed between the field plate and the substrate;
a second portion integral with the first portion and disposed between the gate and the substrate; and
a third portion separate from the first and second portions and disposed between the gate and the field plate.

17. The transistor of claim 11 wherein the insulator includes:
a first portion disposed between the field plate and the substrate;
a second portion integral with the first portion and disposed between the gate and the substrate; and
a third portion integral with the first portion and disposed between the gate and the field plate.

18. The transistor of claim 11, further comprising:
a trench disposed in the substrate; and
wherein the field plate, gate, and insulator are disposed in the trench.

19. The transistor of claim 11, further comprising:
wherein the substrate includes a first boundary and a second boundary that is opposite the first boundary;
a source disposed in the substrate at the first boundary; and
a drain disposed over the second boundary.

20. The transistor of claim 11, further comprising:
a second field plate disposed in the substrate remote from the first field plate;
a second gate disposed in the substrate adjacent to the second field plate; and
a second insulator disposed between the second field plate and the substrate, between the second gate and the substrate, and between the second gate and the second field plate.

21. The transistor of claim 11 wherein:
the substrate includes a boundary;
the gate is disposed over the boundary; and
the insulator is disposed over the boundary between the gate and the substrate.

22. An integrated circuit, comprising:
a substrate; and
a transistor, including
a field plate disposed in the substrate,
a gate disposed in the substrate adjacent to the field plate, and
an insulator disposed between the field plate and the substrate, between the gate and the substrate, and between the gate and the field plate.

23. The integrated circuit of claim 22 wherein the transistor includes a MOS transistor.

24. A system, comprising:
a first integrated circuit, including
a substrate, and P2 a transistor, including
a field plate disposed in the substrate,
a gate disposed in the substrate adjacent to the field plate, and
an insulator disposed between the field plate and the substrate, between the gate and the substrate, and between the gate and the field plate; and
a second integrated circuit coupled to the first integrated circuit.

25. The system of claim 24 wherein the first and second integrated circuits are disposed on an same die.

26. The system of claim 24 wherein the first and second integrated circuits are disposed on respective dies.

27. The system of claim 24 wherein one of the first and second integrated circuits includes a computing apparatus.

28. A method, comprising:
forming a field plate in a substrate;
forming a gate in the substrate adjacent to the field plate;
forming a first insulator between the field plate and the substrate;
forming a second insulator between the gate and the substrate; and
forming a third insulator between the gate and the field plate.

29. The method of claim 28, further comprising:
forming in the substrate a trench having a wall;
wherein forming the first insulator includes forming the first insulator over the wall;
wherein forming the field plate includes forming the field plate in the trench over the first insulator;
removing a portion of the first insulator from the trench;
wherein forming the second insulator includes forming the second insulator over a portion of the wall exposed by the removing of the portion of the first insulator;
wherein forming the third insulator includes forming the third insulator over a portion of the field plate exposed by the removing of the portion of the first insulator; and
wherein forming the gate includes forming the gate in the trench over the first insulator.

30. The method of claim 28, further comprising:
forming in the substrate a trench having a wall;
wherein forming the first insulator includes forming the first insulator over the wall;
wherein forming the field plate includes forming the field plate in the trench over the first insulator;
removing a portion of the first insulator from the trench;
wherein forming the second insulator includes forming a first portion of the second insulator over a portion of the wall of the substrate exposed by removing the portion of the first insulator, and forming a second portion of the second insulator over a portion of a surface of the substrate exposed by the removing of the portion of the first insulator;
wherein forming the third insulator includes forming the third insulator over a portion of the field plate exposed by the removing of the portion of the first insulator; and
wherein forming the gate includes forming the gate in the trench over the first insulator and over the second portion of the second insulator.

31. A method, comprising:
applying to a gate of a transistor a gate voltage; and
applying to a field plate of the transistor a field-plate voltage that is independent of the gate voltage.

32. The method of claim 31 wherein the gate is electrically insulated from the field plate.
